(19) United States
(12) Patent Application Publication
(10) Pub. No.: US 2023/0008712 A1
(43) Pub. Date: Jan. 12, 2023

(54) LED MODULE

(71) Applicant: HYUNDAI MOBIS CO., LTD., Seoul (KR)

(72) Inventors: Ki Hoon CHAE, Yongin-si (KR); Gil Won HAN, Yongin-si (KR); Jae Woo HONG, Yongin-si (KR)

(73) Assignee: HYUNDAI MOBIS CO., LTD., Seoul (KR)

(21) Appl. No.: 17/811,013

(22) Filed: Jul. 6, 2022

(30) Foreign Application Priority Data
Jul. 12, 2021 (KR) 10-2021-0091236
Jul. 12, 2021 (KR) 10-2021-0091237
Jul. 12, 2021 (KR) 10-2021-0091239
Jul. 12, 2021 (KR) 10-2021-0091240
Jul. 12, 2021 (KR) 10-2021-0091241

(51) Int. Cl. F21V 29/503; F21V 29/70

(52) U.S. Cl. CPC F21V 29/503; F21V 29/70; F21Y 2115/10

(57) ABSTRACT

An LED module includes a light emitting part, a board part electrically connected to the light emitting part, and a heat radiating part disposed on a lower side of the light emitting part and the board part, and a surface treatment is applied to the heat radiating part.

### CROSS-REFERENCE TO RELATED APPLICATION

This application claims the benefits of priorities to Korean Patent Application Nos. 10-2021-0091239, 10-2021-0091236, 10-2021-0091237, 10-2021-0091240, and 10-2021-0091241, filed in the Korean Intellectual Property Office on Jul. 12, 2021, the entire contents of which are incorporated herein by reference.

### TECHNICAL FIELD

The present disclosure relates to an LED module.

### BACKGROUND

LED modules are used in various fields, such as lamps for a vehicle. Among the LED modules, an existing SMD type LED module transfers heat generated by LEDs to air through a PCB board and heat radiation component, and thus heat radiation efficiency is relatively low. The low heat radiation efficiency may increase heat emissions of the LEDs and may cause deformation and color problems of optical components.

Accordingly, in recent years, top electrode LED modules have mainly used. The top electrode LED module refers to a structure, in which heat radiation efficiency is increased by directly attaching top electrode LEDs to heat radiating components (a heat sink (H/Sink), a heat plate (H/Plate), and the like), and electric power is transmitted to the LED substrate through wiring lines that connect a separate PCB board and upper end electrode parts of the LEDs.

The heat radiation efficiency of the top electrode LED module is considerably increased as compared with the existing SMD type LED module, but when the heat radiating components are of the plate type (H/Plate), there are limitations in securing shapes and sizes for satisfying necessary heat radiation areas and assembling peripheral mechanisms. Accordingly, a structure for further securing heat radiation efficiency is necessary.

Furthermore, because separate wiring lines for supplying electric currents are structurally exposed to an outside and a separate PCB board for wires and connectors, and other elements is necessary, an assembly structure for them is necessary.

### SUMMARY

The present disclosure has been made to solve the above-mentioned problems occurring in the prior art while advantages achieved by the prior art are maintained intact.

An aspect of the present disclosure provides an LED module that may enhance heat radiation performance and reduce the size and weight thereof.

Another aspect of the present disclosure provides an LED module that may be conveniently assembled, and may not require a separate structure for assembling.

Another aspect of the present disclosure provides an LED module that may protect wiring lines for supplying electric current.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an LED module includes a light emitting part, a board part electrically connected to the light emitting part, and a heat radiating part disposed on a lower side of the light emitting part and the board part, and a surface treatment is applied to the heat radiating part.

In another embodiment, the surface treatment may be anodizing.

In another embodiment, the surface treatment may be thermal coating.

In another embodiment, an outer surface of the heat radiating part may be black colored through the surface treatment.

In another embodiment, an outer surface of the heat radiating part may be deadened through the surface treatment.

In another embodiment, the heat radiating part may include a heat radiating part body configured such that the board part and the light emitting part are seated on an upper surface thereof, and a heat radiating part boss protruding upwards from the heat radiating part body.

In another embodiment, a pair of heat radiating part bosses may be provided, and the board part may be disposed between the pair of heat radiating part bosses.

In another embodiment, the board part may include a first board area electrically connected to the light emitting part and extending rearwards, and a second board area integrally formed with the first board area and protruding leftwards and rightwards from the first board area, the first board area may be disposed between the pair of heat radiating part bosses, and the second board area may be disposed on a rear side of the pair of heat radiating part bosses.

In another embodiment, the LED module may further include an electric line part electrically connecting the light emitting part and the board part, and an upper end of the heat radiating part boss may be located to be higher than an upper end part of the electric line part.

In another embodiment, the electric line part may be spaced apart from the first reference surface downwards when it is assumed that an imaginary surface that simultaneously contacts a front distal end of the heat radiating part and the heat radiating part boss is a first reference surface.

In another embodiment, the LED module may further include an extension part extending upwards from a rear distal end of the heat radiating part, and including a rear extension area, of which an upward/downward length is longer than an upward/downward length of the heat radiating part boss, and the electric line part may be spaced apart from the second reference surface downwards when it is assumed that an imaginary surface that simultaneously contacts an upper end of the rear extension area and the heat radiating part boss is a second reference surface.

In another embodiment, the electric line part may have a shape that is convex upwards.

In another embodiment, the LED module may further include a seating part disposed between the light emitting part and the heat radiating part.

In another embodiment, an upward/downward thickness of the board part may correspond to a total thickness obtained by adding upward/downward thicknesses of the light emitting part and the seating part.

In another embodiment, an area of the seating part may be larger than an area of the light emitting part when viewed from a top.

### BRIEF DESCRIPTION OF THE DRAWINGS

The above and other objects, features and advantages of the present disclosure will be more apparent from the following detailed description taken in conjunction with the accompanying drawings:

FIG. 1 is a perspective view illustrating an LED module according to a first embodiment of the present disclosure;

FIG. 2 is an enlarged view of FIG. 1;

FIG. 3 is a top view of FIG. 1;

FIG. 4 is a bottom view of FIG. 1;

FIG. 5 is a side view of FIG. 1;

FIG. 6 is a rear view of FIG. 1;

FIG. 7 is a perspective view illustrating an LED module according to a second embodiment of the present disclosure;

FIG. 8 is a perspective view illustrating an LED module according to a third embodiment of the present disclosure; and

FIG. 9 is a table representing comparisons of necessary heat radiation areas and weights of heat radiation components when a surface treatment is not applied and when anodizing is applied.

### DETAILED DESCRIPTION

Hereinafter, some embodiments of the present disclosure will be described in detail with reference to the exemplary drawings. In providing reference numerals to the constituent elements of the drawings, the same elements may have the same reference numerals even if they are displayed on different drawings. Further, in the following description of the present disclosure, a detailed description of known functions and configurations incorporated herein will be omitted when it may make the subject matter of the present disclosure rather unclear.

Basic Elements of LED Module According to First Embodiment

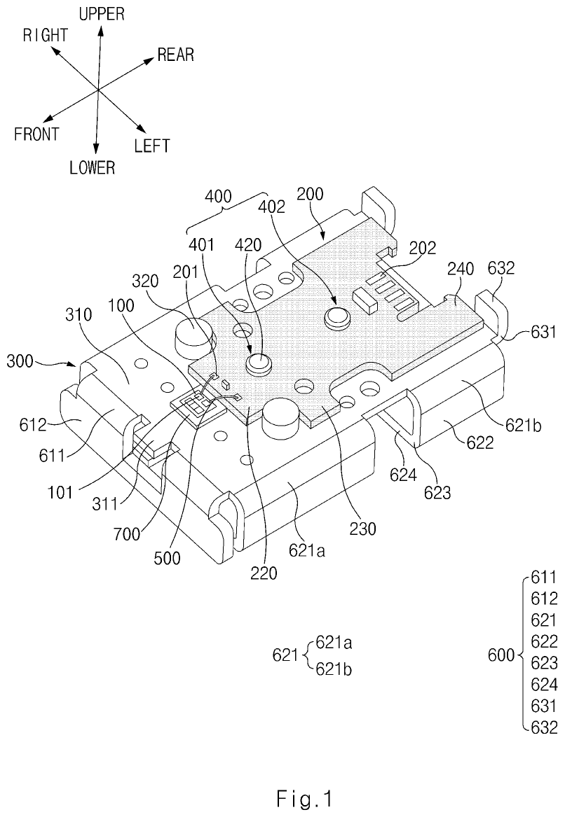

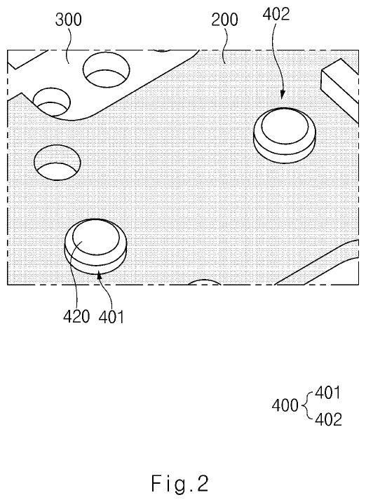

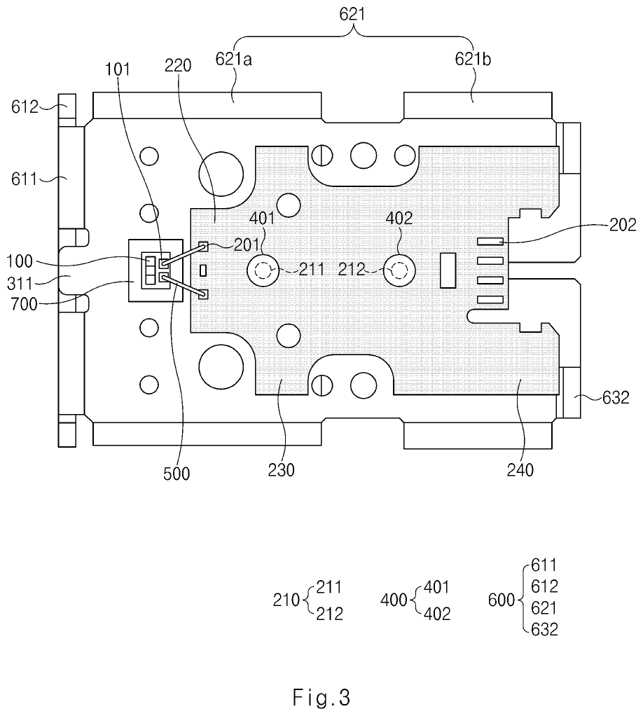

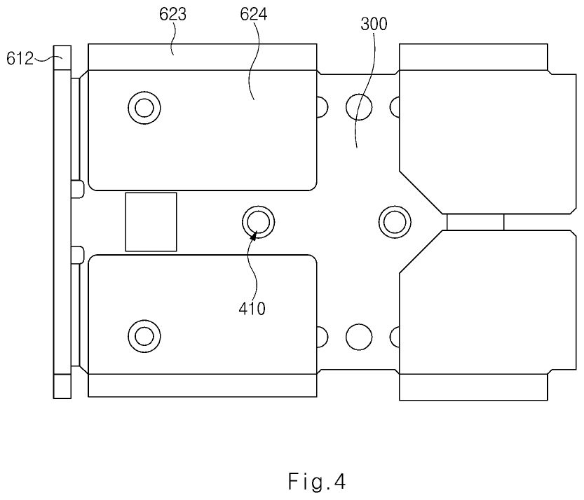

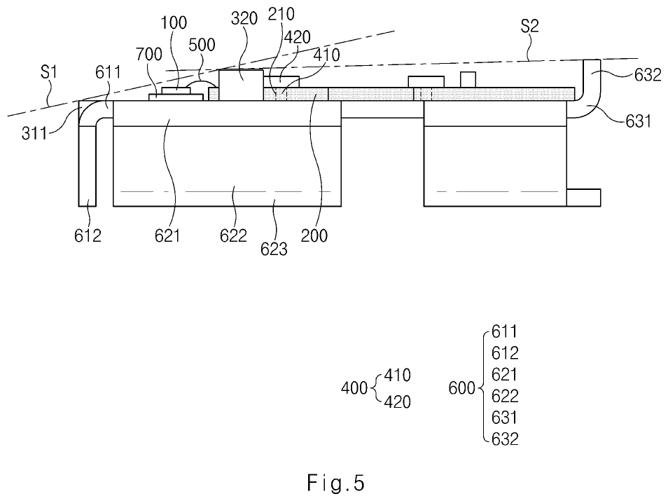

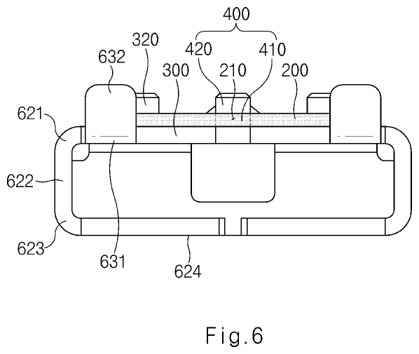

An LED module according to the first embodiment of the present disclosure relates to a top electrode LED. FIG. 1 is a perspective view illustrating the LED module according to the first embodiment of the present disclosure. FIG. 2 is an enlarged view of FIG. 1. FIG. 3 is a top view of FIG. 1. FIG. 4 is a bottom view of FIG. 1. FIG. 5 is a side view of FIG. 1. FIG. 6 is a rear view of FIG. 1.

<Light Emitting Part 100, Board Part 200, and Heat Radiating Part 300>

As illustrated in FIG. 1, the LED module according to the first embodiment of the present disclosure may include the light emitting part 100, the board part 200, and the heat radiating part 300. The light emitting part 100 may be an LED. The light emitting part 100 may include an electrode 101 for electrical connection with external configurations. The board part 200 may be electrically connected to the light emitting part 100. As an example, the board part 200 may be an FR-4 PCB. The board part 200 may include an electrode terminal 201 electrically connected to the electrode 101, and a connector terminal 202, to which a connector is connected. The heat radiating part 300 may be disposed on a lower side of the light emitting part 100 and the board part 200. The heat radiating part 300 may radiate heat generated by the board part 200. The heat radiating part 300 may be disposed to be adhered to the light emitting part 100 and the board part 200.

<Detailed Shape of Heat Radiating Part 300>

As illustrated in FIG. 1, the heat radiating part 300 may include a heat radiating part body 310 and a heat radiating part boss 320. The heat radiating part body 310 may be configured such that the board part 200 and the light emitting part 100 are seated on an upper surface thereof. The heat radiating part boss 320 may protrude upwards from the heat radiating part body 310. The heat radiating part boss 320 may be provided to face a front area of the board part 200.

As illustrated in FIG. 1, a pair of heat radiating part bosses 320 may be provided, and the board part 200 may be disposed between the pair of heat radiating part bosses 320. A shape of the board part 200 will be described in detail to describe the disposition in more detail.

<Detailed Shape of Board Part 200>

As illustrated in FIG. 1, the board part 200 may include a first board area 220 and a second board area 230. The first board area 220 may be electrically connected to the light emitting part 100, and may extend rearwards. The second board area 230 may be integrally formed with the first board area 220, and may protrude leftwards and rightwards from the first board area 220. As illustrated in FIG. 1, the first board area 220 may be disposed between the pair of heat radiating part bosses 320, and the second board area 230 may be disposed on a rear side of the pair of heat radiating part bosses 320. Meanwhile, an area of the board part 200, which faces the heat radiating part boss 320, may have an inwardly recessed shape while having a shape corresponding to the heat radiating part boss 320.

Furthermore, the board part 200 may include a third board area. The third board area may protrude leftwards and rightwards from the first board area 220, and may be disposed to be spaced rearwards apart from the second board area 230. When viewed from a top, the third board area may include an area that protrudes rearwards as compared with the first board area 220.

<Function of Heat Radiating Part Boss 320-Protection of Electric Line Part 500>

As illustrated in FIG. 1, the LED module according to the first embodiment of the present disclosure may further include the electric line part 500. The electric line part 500 may electrically connect the board part 200 and the light emitting part 100. One side of the electric line part 500 may be fixed to the electrode 101, and an opposite side of the electric line part 500 may be fixed to the electrode terminal 201. The electric line part 500 may have an upwardly convex shape.

The heat radiating part boss 320 may function to protect the electric line part 500. Because the heat radiating part boss 320 protects the electric line part 500, a possibility of generating a problem, such as a short circuit, may be decreased, whereby a life span of the LED module may be increased.

This will be described in detail with reference to FIG. 5. As illustrated in FIG. 5, an upper end of the heat radiating part boss 320 may be provided to be higher than an upper end of the electric line part 500. Because the upper end of the heat radiating part boss 320 is higher than the upper end of the electric line part 500, the electric line part 500 may be protected by suppressing an object that approaches the electric line part 500 from a top from contacting the electric line part 500.

Furthermore, the electric line part 500 may be spaced downwards apart from a first reference surface S1. The first reference surface S1 may be an imaginary surface that simultaneously contacts a front distal end of the heat radiating part 300 and the heat radiating part boss 320.

Furthermore, the electric line part 500 may be spaced apart from a second reference surface S2 downwards. The second reference surface S2 may be an imaginary surface that simultaneously contacts an upper end of a rear extension area 632, which will be described below, and the heat radiating part boss 320. Through this, the electric line part 500 may be protected by suppressing an object that approaches the electric line part 500 from contacting the electric line part 500.

<Fastening Part 400>

As illustrated in FIG. 1, the LED module according to the first embodiment of the present disclosure may include the fastening part 400. The fastening part 400 may fasten the heat radiating part 300 and the board part 200. In detail, the board part 200 may include a through-hole 210, through which the fastening part 400 passes.

As illustrated in FIGS. 5 and 6, the fastening part 400 may include a fastening part body 410 and a fastening part head 420. The fastening part body 410 may pass through the through-hole 210, and may be connected to the heat radiating part 300. The though-hole 210 may be a hole provided in the board part 200 such that the fastening part body 410 passes therethough.

The fastening part head 420 may be connected to an upper side of the fastening part body 410, may be located on an upper side of the board part 200, and may have a diameter that is larger than a diameter of the through-hole 210. Furthermore, a diameter of the fastening part head 420 may be larger than a diameter of the fastening part body 410. Because the diameter of the fastening part head 420 is larger than the diameter of the through-hole 210, the board part 200 may be constrained between the fastening part head 420 and the heat radiating part 300.

The fastening part 400 may be integrally formed with the heat radiating part 300. As an example, the fastening part 400 may be extruded together with the heat radiating part 300. Furthermore, the fastening part 400 may be injection-molded together with the heat radiating part 300. Because the fastening part 400 is integrally formed with the heat radiating part 300, a separate configuration (for example, a rivet) for coupling the heat radiating part 300 and the board part 200 is not required, whereby productivity may be increased and manufacturing costs may be reduced.

<Method for Manufacturing LED Module According to First Embodiment>

Hereinafter, a method for manufacturing an LED module according to the first embodiment will be described in detail. The contents that will be described below in detail may be understood as a method for coupling the board part 200 to the heat radiating part 300. The method for manufacturing the LED module according to the first embodiment may include a disposition operation and a machining operation.

The disposition operation may be an operation of locating the board part 200 on an upper side of the heat radiating part 300, and causing the fastening part 400 integrally formed with the heat radiating part 300 to pass through the through-hole 210 of the board part 200. Then, the diameter of the fastening part head 420 may correspond to or be smaller than the diameter of the through-hole 210.

The machining operation is an operation of pressing the fastening part 400 to form the fastening part 400 on an upper side of the through-hole 210, and forming the fastening part head 420 having a diameter that is larger than that of the through-hole 210. As an example, the machining operation may include calking. As another example, the machining operation may include driving.

As described in the above-mentioned contents, a shape of the fastening part head 420 may be changed in the method for manufacturing the LED module according to the first embodiment. The diameter of the fastening part head 420 may correspond to or be smaller than the diameter of the through-hole 210 before the fastening part head 420 is pressed before the LED module is manufactured, and the diameter of the fastening part head 420 may be larger than the diameter of the through-hole 210 as the fastening part head 420 is pressed after passing through the through-hole 210.

As illustrated in FIG. 3, the through-hole 210 may include a first through-hole 211 and a second through-hole 212. The second through-hole 212 may be disposed to be spaced rearwards apart from the first through-hole 211. The fastening part 400 may include a first fastening part 401 and a second fastening part 402. The first fastening part 401 may pass through the first through-hole 211. The second fastening part 402 may pass through the second through-hole 212.

<Extension Part 600>

As illustrated in FIG. 1, the LED module according to the first embodiment of the present disclosure may include an extension part 600. The extension part 600 may extend downwards or upwards from a distal end of the heat radiating part 300. The extension part 600 may be integrally formed with the heat radiating part 300. The LED module according to the first embodiment of the present disclosure has the extension part 600 such that a surface area thereof may be increased, whereby a heat radiation area thereof may be further secured. Hereinafter, the extension part 600 will be described below in detail.

The extension part 600 may include a front bending area 611 and a front extension area 612. The front bending area 611 may be an area that is bent from a front distal end of the heat radiating part 300 toward a lower side and extends. The front bending areas 611 may be disposed to be spaced leftwards and rightwards apart from each other while a boss area 311 being interposed therebetween. The boss area 311 may be an area that protrudes from a portion of the front distal end of the heat radiating part body 310.

The front extension area 612 may be an area that extends downwards from a lower distal end of the front bending area 611. Furthermore, a width of the front extension area 612 may be larger than a width of the heat radiating part body 310.

Furthermore, the extension part 600 may include a first side bending area 621 and a first side extension area 622. The first side bending area 621 may be bent downwards from a distal end of at least any one of the left side and the right side of the heat radiating part 300 and extend. FIG. 1 illustrates a state, in which the first side bending areas 621 extend from both of the left and right sides of the heat radiating part 300.

The first side extension area 622 may extend downwards from a lower distal end of the first side bending area 621. Upward/downward lengths of the front bending area 611 and the first side bending area 621 may correspond to each other. Furthermore, upward/downward lengths of the front extension area 612 and the first side extension area 622 may correspond to each other.

The extension part 600 may include a second side bending area 623 and a second side extension area 624. The second side bending area 623 may extend toward an inner side from a lower distal end of the first side extension area 622. Here, the inner side may mean the left side when it extends from a right distal end of the heat radiating part body 310 and mean the right side when it extends from a left distal end thereof. The entire shape, in which the first side bending area 621, the first side extension area 622, and the second side bending area 623 are connected to each other, may be similar to a shape obtained by rotating a ‘C’ shape or a CU′ shape as a whole.

The second side extension area 624 may extend inwards from an inner distal end of the second side bending area 623. A width of the second side extension area 624 may be shorter than a half of a width of the heat radiating part 300.

The first side bending area 621 may include a (1-1)-th side bending area 621a and a (1-2)-th side bending area 621b. The (1-1)-th side bending area 621a may be an area that is disposed adjacent to the front distal end of the heat radiating part 300. The (1-2)-th side bending area 621b may be an area that is spaced rearwards apart from the (1-1)-th side bending area 621a.

The first side bending area 621a may be connected to a (1-1)-th side extension area, a (2-1)-th side bending area, and a (2-1)th side extension area, and the (1-2)-th side bending area 621b may be connected to a (1-2)-th side extension area, a (2-2)-th side bending area, and a (2-2)th side extension area. A detailed description thereof corresponds to the descriptions of the first side extension area 622, the second side bending area 623, and the second side extension area 624, and thus will be omitted.

The extension part 600 may include a rear bending area 631 and the rear extension area 632. The rear bending area 631 may be an area that is bent from a rear distal end of the heat radiating part 300 toward an upper side and extends. As illustrated in FIG. 1, the rear bending area 631 may protrude leftwards and rightwards as compared with the board part 200. The rear extension area 632 may extend upwards from an upper distal end of the rear bending area 631.

<Seating Part 700>

As illustrated in FIG. 1, the LED module according to the first embodiment of the present disclosure may further include the seating part 700. The seating part 700 may be disposed between the light emitting part 100 and the heat radiating part 300. As illustrated in FIG. 3, when viewed from a top, an area of the seating part 700 may be larger than an area of the light emitting part 100. As illustrated in FIG. 5, an upward/downward thickness of the board part 200 may correspond to a thickness obtained by adding the upward/downward thicknesses of the light emitting part 100 and the seating part 700.

LED Module According to Second Embodiment

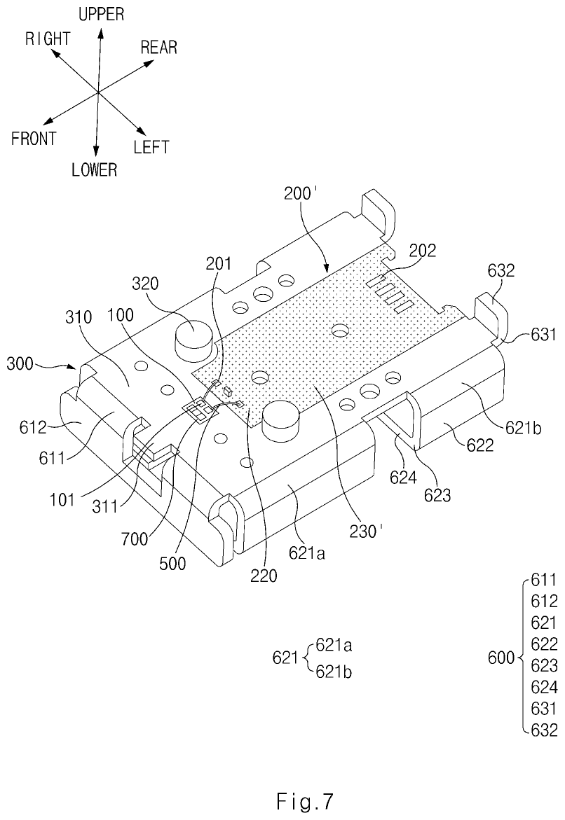

FIG. 7 is a perspective view illustrating the LED module according to the second embodiment of the present disclosure. Hereinafter, the LED module according to the second embodiment of the present disclosure will be described with reference to FIGS. 7 and 1 to 6.

The LED module according to the second embodiment of the present disclosure is different from the LED module according to the first embodiment in aspects of the kind of a board part 200′ and a coupling scheme of the heat radiating part and the board part. Furthermore, accordingly, it is different from the LED module according to the first embodiment in aspects of presence of the fastening part and presence of the seating part. The same or corresponding reference numerals are given to configurations that are the same as or correspond to those of the LED module according to the first embodiment, and a detailed description thereof will be omitted.

The LED module according to the second embodiment of the present disclosure may include the light emitting part 100, the board part 200′, and the heat radiating part 300. The board part 200′ may be a flexible PCB. Because the LED module according to the second embodiment of the present disclosure uses a flexible printed circuit board, a thickness of the board part 200′ may be a small thickness (0.1T to 0.2T) that is smaller than a thickness of a general FR-4 PCB, whereby heat radiation performance may be secured by enhancing thermal conductivity.

In more detail, the flexible printed circuit board is mainly formed of a flexible copper clad laminate (FCCL), and has a form, in which an insulation film, a conductor, and a protection film are combined. That is, because it has a form, in which a copper layer for a circuit pattern/element mounting part is positioned on a material, such as a thin film, it may have a small thickness of 0.1T to 0.2T.

As an example, the flexible printed circuit board may be coupled to a base plate. The base plate may be coupled to the flexible printed circuit board for preventing burn-out of an element. Furthermore, because the base plate is coupled to the flexible printed circuit board, a planar state of the flexible printed circuit board may be maintained well, and heat radiation performance may be further secured.

The heat radiating part 300 may be attached to a lower side of the board part 200′. For example, the board part 200′ may be attached to an upper side of the heat radiating part 300 through a thermosetting treatment. For example, the board part 200′ may be attached to an upper side of the heat radiating part 300 through a pressure sensitive attachment scheme.

According to the LED module according to the second embodiment of the present disclosure, because the board part 200′ is attached to the heat radiating part 300, an assembly process for coupling the board part 200′ and the heat radiating part 300 may be deleted, whereby productivity may be enhanced.

As illustrated in FIG. 7, the second board area 230′ may overlap portions of inner sides of the pair of heat radiating part bosses 320. Furthermore, an upward/downward thickness of the board part 200′ may be smaller than the upward/downward thickness of the light emitting part 100.

<Method for Manufacturing LED Module According to Second Embodiment>

Hereinafter, a method for manufacturing an LED module according to the second embodiment will be described in detail. The contents that will be described below in detail may be understood as a method for attaching the board part 200′ to the heat radiating part 300. The method for manufacturing the LED module according to the second embodiment may include an attachment operation of attaching the board part 200′ to an upper side of the heat radiating part 300. The attachment operation may be an operation of attaching the board part 200′ to the upper side of the heat radiating part 300 through a thermosetting treatment. As another example, the attachment operation may be an operation of attaching the board part to the upper side of the heat radiating part 300 through a pressure sensitive attachment scheme.

The thermosetting treatment operation may be an operation of attaching the board part 200′ to the upper side of the heat radiating part 300 through a thermosetting treatment by using a thermosetting tape. After the thermosetting treatment operation, an element mounting process and the like through an OSP surface treatment or an SMT reflow process may be performed.

The pressure sensitive attachment scheme may be an operation of attaching the board part 200′ to the upper side of the heat radiating part 300 through a general resistive double-sided tape.

According to the method for manufacturing an LED module according to the second embodiment of the present disclosure, due to the small thickness of the board part 200′, the board part 200 may be directly attached to the heat radiating part 300 through the thermosetting treatment or the pressure sensitive attachment scheme, instead of a separate complex fastening process, whereby the process may become efficient.—

LED Module According to Third Embodiment

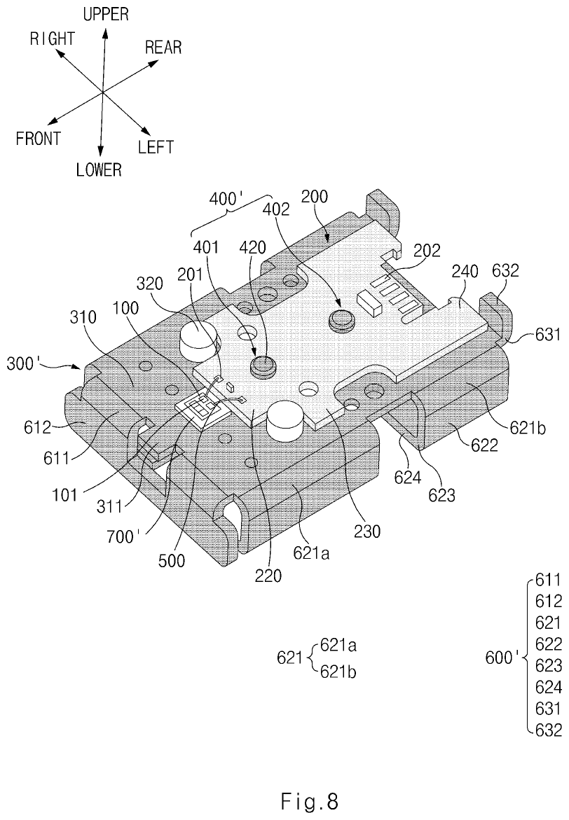

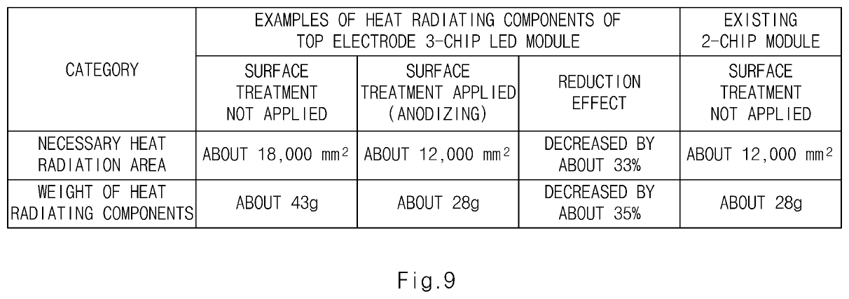

FIG. 8 is a perspective view illustrating an LED module according to a third embodiment of the present disclosure. FIG. 9 is a table representing comparisons of necessary heat radiation areas and weights of heat radiation components when a surface treatment is not applied and when anodizing is applied. Hereinafter, the LED module according to the third embodiment of the present disclosure will be described with reference to FIGS. 8 to 9 and 1 to 6.

The LED module according to the third embodiment of the present disclosure is different from the LED module according to the first embodiment in an aspect of a surface treatment of a heat radiating part 300′. The same or corresponding reference numerals are given to configurations that are the same as or correspond to those of the LED module according to the first embodiment, and a detailed description thereof will be omitted.

A surface treatment may be applied to the heat radiating part 300′ of the LED module according to the third embodiment of the present disclosure. The surface treatment of the heat radiating part 300′ may be applied to a fastening part 400′, an extension part 600′, and a seating part 700′, which may be integrally formed with the heat radiating part 300′ in the same way.

As an example, the surface treatment may be anodizing. As another example, the surface treatment may be thermal coating. FIG. 9 is a table representing comparisons of necessary heat radiation areas and weights of heat radiation components when a surface treatment is not applied and when anodizing is applied.

As illustrated in FIG. 9, because the heat radiating part is surface-treated, heat radiation efficiency may be enhanced, and a necessary heat radiation area may be decreased by 30% or more. Because the necessary heat radiation area is minimized, the entire size of the LED module may be minimized, and weight may be reduced by 30% or more.

Furthermore, because heat radiation performance is increased through the surface treatment, the light emitting part having a higher specification may be accommodated in the heat radiating part of the same shape. For example, after the heat radiator used for the light emitting part that employs two chips is surface-treated, it may be applied to the light emitting part that employs three chips. Accordingly, there is no need to separately manufacture molds according to the specifications of the light emitting part, the mold may be unified, and manufacturing costs may be reduced.

As another example, an outer surface of the heat radiation part 300′ may be black colored through a surface treatment. As another example, an outer surface of the heat radiating part 300′ may be deadened through a surface treatment.

In a general LED module, when the LEDs and peripheral areas thereof become vulnerable parts according to a sunlight lighting angle, the LED module and peripheral mechanisms thereof (due to reflection) may be damaged, for example, may be deformed and discolored due to the condensed light and heat and durability may be degraded. The LED module according to the third embodiment of the present disclosure may prevent damages, such as deformation and discoloring, and degradation of durability by adjusting surface colors and reflectivity.

According to the present disclosure, because wiring lines for supplying electric currents may be protected through the heat radiating part boss protruding upwards from the heat radiating part, a life span of the LED module may be increased.

Furthermore, according to the present disclosure, a surface area of the heat radiating part may be increased and heat radiation performance may be enhanced, whereby a size and a weight of the heat radiating part may be reduced.

Furthermore, according to the present disclosure, because a structure for assembling the heat radiating part and the board part are formed in the heat radiating part, an assembling process may be convenient and a separate structure for assembling may not be required, whereby productivity may be enhanced.

Furthermore, according to the present disclosure, because the board part may be attached to the heat radiating part, an assembling process may be convenient and a separate structure for assembling may not be required, whereby productivity may be enhanced.

Furthermore, according to the present disclosure, because the outer surface of the heat radiating part is surface-treated, heat radiation performance may be enhanced, whereby a size and a weight of the heat radiating part may be reduced.

The above description is a simple exemplification of the technical spirits of the present disclosure, and the present disclosure may be variously corrected and modified by those skilled in the art to which the present disclosure pertains without departing from the essential features of the present disclosure. Accordingly, the embodiments disclosed in the present disclosure is not provided to limit the technical spirits of the present disclosure but provided to describe the present disclosure, and the scope of the technical spirits of the present disclosure is not limited by the embodiments. Accordingly, the technical scope of the present disclosure should be construed by the attached claims, and all the technical spirits within the equivalent ranges fall within the scope of the present disclosure.

What is claimed is:

1. An LED module comprising:
a light emitting part;
a board part electrically connected to the light emitting part; and
a heat radiating part disposed on a lower side of the light emitting part and the board part,
wherein a surface treatment is applied to the heat radiating part.

2. The LED module of claim 1, wherein the surface treatment comprises anodizing.

3. The LED module of claim 1, wherein the surface treatment comprises thermal coating.

4. The LED module of claim 1, wherein an outer surface of the heat radiating part is black colored through the surface treatment.

5. The LED module of claim 1, wherein an outer surface of the heat radiating part is deadened through the surface treatment.

6. The LED module of claim 1, wherein the heat radiating part comprises:
a heat radiating part body configured such that the board part and the light emitting part are seated on an upper surface thereof; and
a heat radiating part boss protruding upwards from the heat radiating part body.

7. The LED module of claim 6, wherein a pair of heat radiating part bosses are provided, and
wherein the board part is disposed between the pair of heat radiating part bosses.

8. The LED module of claim 7, wherein the board part comprises:
a first board area electrically connected to the light emitting part and extending rearwards; and
a second board area integrally formed with the first board area and protruding leftwards and rightwards from the first board area,
wherein the first board area is disposed between the pair of heat radiating part bosses, and the second board area is disposed on a rear side of the pair of heat radiating part bosses.

9. The LED module of claim 6, further comprising:
an electric line part electrically connecting the light emitting part and the board part,
wherein an upper end of the heat radiating part boss is located to be higher than an upper end part of the electric line part.

10. The LED module of claim 9, wherein the electric line part is spaced apart from a first reference surface when an imaginary surface that simultaneously contacts a front distal end of the heat radiating part and the heat radiating part boss is the first reference surface.

11. The LED module of claim 10, further comprising:
an extension part extending upwards from a rear distal end of the heat radiating part, and including a rear extension area, of which an upward/downward length is longer than an upward/downward length of the heat radiating part boss,
the electric line part is spaced apart from a second reference surface downwards when an imaginary surface that simultaneously contacts an upper end of the rear extension area and the heat radiating part boss is the second reference surface.

12. The LED module of claim 9, wherein the electric line part has a convex shape.

13. The LED module of claim 1, further comprising:
a seating part disposed between the light emitting part and the heat radiating part.

14. The LED module of claim 13, wherein an upward/downward thickness of the board part corresponds to a total thickness obtained by adding upward/downward thicknesses of the light emitting part and the seating part.

15. The LED module of claim 13, wherein an area of the seating part is larger than an area of the light emitting part when viewed from a top-down direction.
